(19) United States
(12) Patent Application Publication
(10) Pub. No.: US 2025/0143093 A1
(43) Pub. Date: May 1, 2025

(54) DISPLAY DEVICE AND MOTHERBOARD FOR DISPLAY DEVICE

(71) Applicant: Japan Display Inc., Tokyo (JP)

(72) Inventors: Naoya IWAHASHI, Tokyo (JP); Sho YANAGISAWA, Tokyo (JP)

(73) Assignee: Japan Display Inc., Tokyo (JP)

(21) Appl. No.: 18/921,030

(22) Filed: Oct. 21, 2024

(30) Foreign Application Priority Data
Oct. 25, 2023 (JP) 2023-183189

(51) Int. Cl. H10K 59/122; H10K 59/35

(52) U.S. Cl. CPC H10K 59/122; H10K 59/351; H10K 59/352

(57) ABSTRACT

According to one embodiment, a display device includes a substrate, an organic insulating layer disposed above the substrate over a display area in which a plurality of display elements are disposed and over a peripheral area, a first partition disposed between the display elements adjacent to each other, and a second partition disposed in the peripheral area. The first partition and the second partition each include a conductive lower portion and an upper portion protruding from a side surface of the lower portion, the organic insulating layer includes an aperture in the peripheral area, and the second partition is disposed along an edge of the aperture on an outer side of the aperture.

### CROSS-REFERENCE TO RELATED APPLICATION

This application is based upon and claims the benefit of priority from Japanese Patent Application No. 2023-183189, filed Oct. 25, 2023, the entire contents of which are incorporated herein by reference.

### FIELD

Embodiments described herein relate generally to a display device and a motherboard for display device.

### BACKGROUND

In recent years, display devices in which organic light emitting diodes (OLEDs) are applied as display elements have been put to practical use. Such display devices comprise a lower electrode, an organic layer that covers the lower electrode, and an upper electrode that covers the organic layer.

In the manufacture of such display devices as described above, there is a need for a technology for improving the yield in the manufacturing process.

### BRIEF DESCRIPTION OF THE DRAWINGS

FIG. 1 is a diagram showing a configuration example of a display device according to the first embodiment.

FIG. 2 is a plan view schematically showing an example of layout of subpixels.

FIG. 3 is a cross-sectional view schematically showing the display device taken along the line III-III in FIG. 2.

FIG. 4 is a diagram showing an example of a layer structure that can be applied to an organic layer.

FIG. 5 is a plan view showing an example of a motherboard for a display device according to the first embodiment.

FIG. 6 is a plan view showing a configuration example of a pad.

FIG. 7 is a plan view showing a configuration example of a region including pads in a peripheral area or a margin portion.

FIG. 8 is a plan view showing a configuration example of a region including window portions in a peripheral area or a margin portion.

FIG. 9 is a partially enlarged view a schematically showing a part IX in FIGS. 7 and 8.

FIG. 10 is a cross-sectional view schematically showing the motherboard for display device taken along the line X-X line in FIG. 7.

FIG. 11 is a cross-sectional view schematically showing another configuration example of the motherboard for display device.

FIG. 12 is a cross-sectional view schematically showing still another configuration example of the motherboard for display device.

FIG. 13 is a cross-sectional view schematically showing still another configuration example of the motherboard for display device.

FIG. 14 is a cross-sectional view schematically showing still another configuration example of the motherboard for display device.

FIG. 15 is a cross-sectional view schematically showing still another configuration example of the motherboard for display device.

FIG. 16 is a cross-sectional view schematically showing still another configuration example of the motherboard for display device.

FIG. 17 is a cross-sectional view schematically showing the motherboard for display device, taken along the line XVII-XVII in FIG. 8.

FIG. 18 is a cross-sectional view schematically showing another configuration example of the motherboard for display device.

FIG. 19 is a cross-sectional view schematically showing still another configuration example of the motherboard for display device.

FIG. 20 is a cross-sectional view schematically showing still another configuration example of the motherboard for display device.

FIG. 21 is a cross-sectional view schematically showing still another configuration example of the motherboard for display device.

FIG. 22 is a cross-sectional view schematically showing still another configuration example of the motherboard for display device.

FIG. 23 is a cross-sectional view schematically showing still another configuration example of the motherboard for display device.

FIG. 24 is a cross-sectional view schematically showing still another configuration example of the motherboard for display device.

FIG. 25 is a cross-sectional view schematically showing still another configuration example of the motherboard for display device.

FIG. 26 is a cross-sectional view schematically showing still another configuration example of the motherboard for display device.

FIG. 27 is a plan view schematically showing a region including pads in a peripheral area or a margin portion in the second embodiment.

FIG. 28 is a partial enlarged view of part XXVIII in FIG. 27.

FIG. 29 is a plan view schematically showing a region including pads in a peripheral area or a margin portion in the third embodiment.

FIG. 30 is a plan view schematically showing a region including pads in a peripheral area or a margin portion in the fourth embodiment.

FIG. 31 is a plan view schematically showing a region including pads in a peripheral area or a margin portion in the fifth embodiment.

FIG. 32 is a plan view schematically showing a region including pads in a peripheral area or a margin portion in the sixth embodiment.

FIG. 33 is a plan view schematically showing a region including pads in a peripheral area or a margin portion in the seventh embodiment.

FIG. 34 is a plan view schematically showing a region including pads in a peripheral area or a margin portion in the eighth embodiment.

FIG. 35 is a plan view schematically showing a region including pads in a peripheral area or a margin portion in the ninth embodiment.

FIG. 36 is a plan view schematically showing a region including pads in a peripheral area or a margin portion in the tenth embodiment.

FIG. 37 is a diagram illustrating another shape of apertures applicable to the window portions.

### DETAILED DESCRIPTION

In general, according to one embodiment, a display device comprises a substrate, an organic insulating layer disposed above the substrate over a display area in which a plurality of display elements are disposed and over a peripheral area around the display area, a first partition disposed between the display elements adjacent to each other above the organic insulating layer, and a second partition disposed in the peripheral area. The first partition and the second partition each include a conductive lower portion and an upper portion protruding from a side surface of the lower portion. The organic insulating layer includes an aperture in the peripheral area. The second partition is disposed along an edge of the aperture on an outer side of the aperture.

According to another embodiment, a motherboard for a display device, comprises a panel portion including a display area which displays images and a peripheral area around the display area, a margin portion on an outer side of the panel portion, an organic insulating layer disposed over the panel portion and the margin portion, a first partition disposed in the display area above the organic insulating layer and a second partition disposed in the margin portion. The first partition and the second partition each include a conductive lower portion and an upper portion protruding from a side surface of the lower portion. The organic insulating layer includes an aperture in the margin portion. The second partition is disposed along an edge of the aperture on an outer side of the aperture.

With configurations such as described above, it is possible to provide a display device and a motherboard for a display device, which can improve the yield in the manufacturing process.

Embodiments will be described hereinafter with reference to the accompanying drawings. Note that the disclosure is merely an example, and proper changes within the spirit of the invention, which are easily conceivable by a skilled person, are included in the scope of the invention as a matter of course.

In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as an X direction or a first direction, a direction along the Y axis is referred to as a Y direction or a second direction and direction along the Z axis is referred to as a Z direction or a third direction. The Z direction is a direction normal to a plane including the X direction and the Y direction. In each embodiment, the X direction corresponds to the first direction and the Y direction corresponds to the second direction. Further, viewing the constitutional elements parallel to the Z direction is referred to as plan view.

The display device of each of the embodiments is an organic electroluminescent display device equipped with an organic light emitting diode (OLED) as a display element, and can be mounted in various electronic devices such as TVs, personal computers, in-vehicle equipment, tablet terminals, smartphones, cell phone terminals, wearable terminals and the like.

### First Embodiment

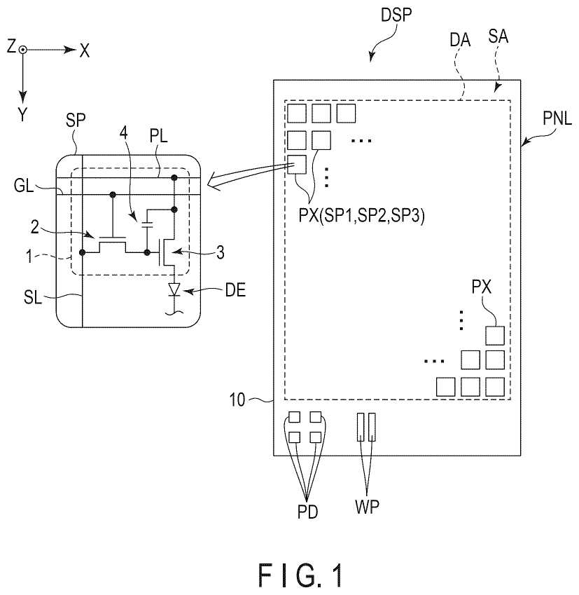

FIG. 1 is a diagram showing a configuration example of a display device DSP according to this embodiment. The display device DSP comprises a display panel PNL including a display area DA that displays images and a peripheral area SA around the display area DA on an insulating substrate 10. In the display area DA, a plurality of display elements, which will be described later, are arranged. The substrate 10 may be glass or a flexible resin film.

In this embodiment, the shape of the substrate 10 in plan view is rectangular. Note here that the shape of the substrate 10 in plan view is not limited to rectangular, and may be some other shape such as square, circle or oval.

The display area DA comprises a plurality of pixels PX arranged in a matrix along the X direction and the Y direction. The pixels PX each contain a plurality of subpixels SP that display colors different from each other. In this embodiment, it is assumed that each pixel PX contains a blue subpixel SP1, a green subpixel SP2, and a red subpixel SP3. Note that the pixels PX may as well contain a subpixel SP of some another color such as white, together with or in place of any of the subpixels SP1, SP2, and SP3.

The subpixels SP each contains a pixel circuit 1, and a display element DE to be driven by the pixel circuit 1. The pixel circuit 1 comprises a pixel switch 2, a drive transistor 3, and a capacitor 4. The pixel switch 2 and the drive transistor 3 are switching elements each constituted by a thin-film transistor, for example.

In the display area DA, a plurality of scanning lines GL, which supply scanning signals to the pixel circuits 1 of the subpixels SP, respectively, a plurality of signal lines SL, which supply video signals to the pixel circuits 1 of the subpixels SP, respectively, and a plurality of power lines PL are arranged. In the example shown in FIG. 1, the scanning lines GL and the power lines PL extend along the X direction, and the signal lines SL extend along the Y direction.

The gate electrode of each pixel switch 2 is connected to a respective one of the scanning lines GL. One of the source electrode and drain electrode of the pixel switch 2 is connected to a respective one of the signal lines SL, and the other is connected to the gate electrode of the drive transistor 3 and the capacitor 4.

In the drive transistor 3, one of the source electrode and drain electrode is connected to a respective one of the power lines PL and the capacitor 4, and the other is connected to the display element DE. Note that the configuration of the pixel circuit 1 is not limited to that of the example shown in the figure. For example, the pixel circuit 1 may contain more thin-film transistors and capacitors.

In the peripheral area SA, pads PD which are used for inspection and the like and window portions WP, are provided. Note that a plurality of pads PD and window portions WP are provided in the example shown in FIG. 1, but the number of pads PD and window portions WP may be changed as needed. In the display panel PNL, either the pads PD or the window portions WP may be omitted.

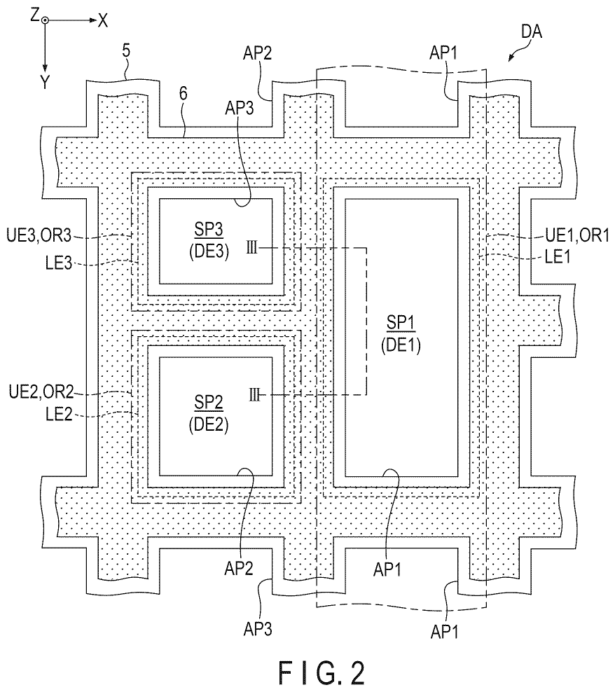

FIG. 2 is a plan view schematically showing an example of layout of the subpixels SP1, SP2, and SP3. In the example shown in FIG. 2, the subpixels SP2 and SP3 are each aligned with the subpixel SP1 along the X direction. Further, the subpixel SP2 and the subpixel SP3 are aligned with each other along the Y direction.

When the subpixels SP1, SP2, and SP3 are arranged in such a layout, rows in each of which the subpixels SP2 and SP3 are arranged alternately along the Y direction and rows in each of which a plurality of the subpixels SP1 are arranged repeatedly along the Y direction are formed in the display area DA. These rows are alternately arranged along the X direction. Note that the layout of the subpixels SP1, SP2, and SP3 is not limited to that of the example shown in FIG. 2.

In the display area DA, an inorganic insulating layer 5 is provided. The inorganic insulating layer 5 has pixel apertures AP1, AP2, and AP3 in the subpixels SP1, SP2, and SP3, respectively. The inorganic insulating layers 5 with pixel apertures AP1, AP2, and AP3 may as well be referred to as a rib.

In the example shown in FIG. 2, the pixel aperture AP1 is larger in size than the pixel aperture AP2, and the pixel aperture AP2 is larger than the pixel aperture AP3. In other words, of the subpixels SP1, SP2, and SP3, the subpixel SP1 has the largest aperture ratio and the subpixel SP3 has the smallest aperture ratio.

The subpixel SP1 contains a lower electrode LE1, an upper electrode UE1, and an organic layer OR1, each of which overlaps the pixel aperture AP1. The subpixel SP2 contains a lower electrode LE2, an upper electrode UE2, and an organic layer OR2, each of which overlaps the pixel aperture AP2. The subpixel SP3 contains a lower electrode LE3, an upper electrode UE3, and an organic layer OR3, each of which overlaps the pixel aperture AP3.

The portions of the lower electrode LE1, the upper electrode UE1 and the organic layer OR1 that overlap the pixel aperture AP1 constitute the display element DE1 of the respective subpixel SP1. The portions of the lower electrode LE2, the upper electrode UE2, and the organic layer OR2 that overlap the pixel aperture AP2 constitute the display element DE2 of the respective subpixel SP2. The portions of the lower electrode LE3, the upper electrode UE3 and the organic layer OR3 that overlap the pixel aperture AP3 constitute the display element DE3 of the respective subpixel SP3. The display elements DE1, DE2, and DE3 may further include a cap layer, which will be described later.

In the display area DA, a conductive partition 6 (first partition) is disposed. The partition 6 is located on the inorganic insulating layer 5. The partition 6 has a planar shape similar to that of the inorganic insulating layer 5 and entirely overlaps the inorganic insulating layer 5. The partition 6 is placed between each adjacent pair made by any of the display elements DE1, DE2, and DE3.

That is, the partition 6 has apertures in the subpixels SP1, SP2, and SP3, respectively. The inorganic insulating layer 5 and the partition 6 are formed into a grid-like shape in plan view and surround each of the subpixels SP1, SP2, SP3. The partition 6 serves as wiring lines that supply a common voltage to the upper electrodes UE1, UE2, and UE3.

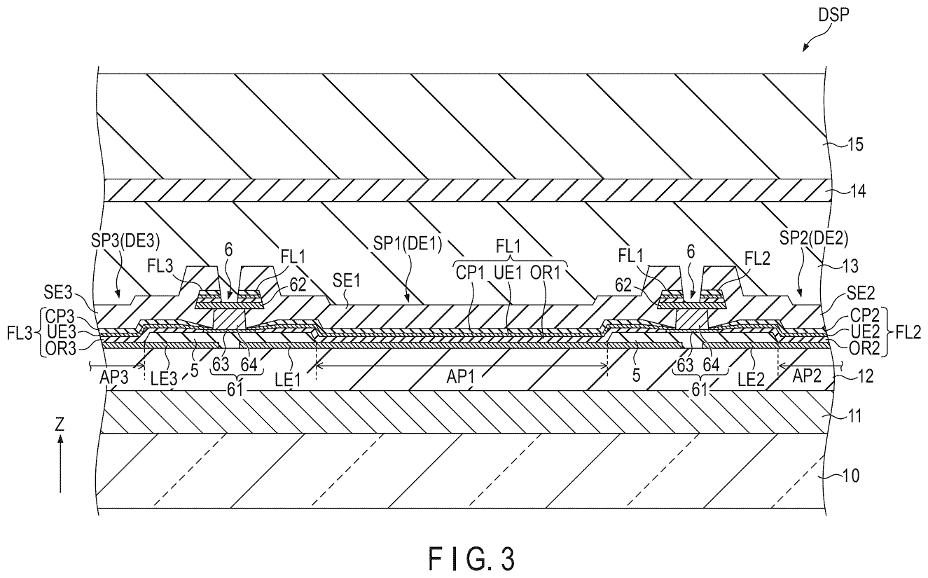

FIG. 3 is a cross-sectional view schematically showing the display device DSP taken along the line III-III in FIG. 2. On the substrate 10 described above, a circuit layer 11 is disposed. The circuit layer 11 contains various circuits and wiring lines including the pixel circuit 1, the scanning lines GL, the signal lines SL, and the power lines PL shown in FIG. 1. The circuit layer 11 is covered by an insulating layer 12. The insulating layer 12 is an organic insulating layer that serves as a planarization film to planarize the unevenness caused by the circuit layer 11.

The lower electrodes LE1, LE2, and LE3 are located on the insulating layer 12. The inorganic insulating layer 5 is disposed on the insulating layer 12 as well as the lower electrodes LE1, LE2, and LE3. End portions of the lower electrodes LE1, LE2, and LE3 are covered by the inorganic insulating layer 5.

Although not illustrated in the cross section of FIG. 3, the lower electrodes LE1, LE2, LE3 are connected to the pixel circuit 1 of the circuit layer 11 via contact holes made in the insulating layer 12, respectively.

The partition 6 includes a conductive lower portion 61 disposed on the inorganic insulating layer 5 and an upper portion 62 disposed on the lower portion 61. The upper portion 62 has a width greater than that of the lower portion 61. With this configuration, both end portions of the upper portion 62 protrude beyond the respective side surfaces of the lower portion 61. Such a shape of the partition 6 is referred to as overhanging shape.

In the example shown in FIG. 3, the lower portion 61 includes a bottom layer 63 disposed on the inorganic insulating layer 5 and an axial layer 64 disposed on the bottom layer 63. For example, the bottom layer 63 is formed thinner than the axial layer 64. Further, in the example shown in FIG. 3, both end portions of the bottom layer 63 protrude from the respective side surfaces of the axial layer 64.

The organic layer OR1 covers the lower electrode LE1 via the pixel aperture AP1. The upper electrode UE1 covers the organic layer OR1 and opposes the lower electrode LE1. The organic layer OR1 is disposed between the lower electrode LE1 and the upper electrode UE1.

The organic layer OR2 covers the lower electrode LE2 via the pixel aperture AP2. The upper electrode UE2 covers the organic layer OR2 and opposes the lower electrode LE2. The organic layer OR3 covers the lower electrode LE3 via the pixel aperture AP3. The upper electrode UE3 covers the organic layer OR3 and opposes the lower electrode LE3. The upper electrodes UE1, UE2, and UE3 are in contact with the side surfaces of the lower portion 61 of the partition 6.

The display element DE1 includes a cap layer CP1 disposed on the upper electrode UE1. The display element DE2 includes a cap layer CP2 disposed on the upper electrode UE2. The display element DE3 includes a cap layer CP3 disposed on the upper electrode UE3. The cap layers CP1, CP2, and CP3 each serve as an optical adjustment layer that improves the efficiency of extraction of light emitted by the organic layers OR1, OR2, and OR3, respectively.

In the following descriptions, the multilayer body containing the organic layer OR1, the upper electrode UE1, and the cap layer CP1 is referred to as a multilayer film FL1, the multilayer body containing the organic layer OR2, the upper electrode UE2, and the cap layer CP2 is referred to as a multilayer film FL2, and the multilayer containing the organic layer OR3, the upper electrode UE3, and the cap layer CP3 is referred to as a multilayer film FL3.

A part of the multilayer film FL1 is located on the upper portion 62. This part is separated apart from a portion of the multilayer film FL1, which is located under the partition 6(, that is, the portion that constitutes the display element DE1). Similarly, a part of the multilayer film FL2 is located on the upper portion 62, and this part is separated apart from the portion of the multilayer film FL2, which is located under the partition 6(, that is, the portion that constitutes the display element DE2). Further, a part of the multilayer film FL3 is located on the upper portion 62, and this part is separated apart from the portion of the multilayer film FL3, which is located under the partition 6(, that is, the portion that constitutes the display element DE3).

In the subpixels SP1, SP2, and SP3, sealing layers SE1, SE2, and SE3 are located, respectively. The sealing layer SE1 continuously covers the cap layer CP1 and the partition 6 around the subpixel SP1. The sealing layer SE2 continuously covers the cap layer CP2 and the partition 6 around the subpixel SP2. The sealing layer SE3 continuously covers the cap layer CP3 and the partition 6 around the subpixel SP3.

In the example shown in FIG. 3, the multilayer film FL1 and the sealing layer SE1 on the partition 6 between the subpixels SP1 and SP2 are separated apart from the multilayer film FL2 and the sealing layer SE2 on the partition 6, respectively. Further, the multilayer film FL1 and the sealing layer SE1 on the partition 6 between the subpixels SP1 and SP3 are separated apart from the multilayer film FL3 and the sealing layer SE3 on the partition 6, respectively.

The sealing layers SE1, SE2, and SE3 are covered by a resin layer 13. The resin layer 13 is covered by a sealing layer 14. The sealing layer 14 is covered by a resin layer 15. The resin layers 13 and 15 and the sealing layer 14 are continuously provided at least over the entire display area DA, and a part thereof extends to the peripheral area SA.

Cover members such as polarizers, touch panels, protective films or cover glass and the like may be further disposed above the resin layer 15. Such cover members may be bonded to the resin layer 15 via, for example, an adhesive layer such as of optical clear adhesive (OCA).

The insulating layer 12 is formed of an organic insulating material such as polyimide. The inorganic insulating layer 5 and the sealing layers 14, SE1, SE2, and SE3 are each formed of an inorganic insulating material such as silicon nitride (SiNx), silicon oxide (SiO_{X}), silicon oxynitride (SiON) or aluminum oxide (Al₂O₃).

For example, the inorganic insulating layer 5 is formed of silicon oxynitride, and the sealing layers 14, SE1, SE2, and SE3 are formed of silicon nitride. The resin layers 13 and 15 are each formed, for example, of a resin material (organic insulating material) such as epoxy resin or acrylic resin.

The lower electrodes LE1, LE2, and LE3 each include a reflective layer formed of silver, for example, and a pair of conductive oxide layers that respectively cover the upper surface and lower surface of the reflective layer. Each of the conductive oxide layer can be formed, for example, of a transparent conductive oxide such as indium tin oxide (ITO), indium zinc oxide (IZO) or indium gallium zinc oxide (IGZO).

The upper electrodes UE1, UE2, and UE3 are each formed, for example, of a metal material such as an alloy of magnesium and silver (MgAg). For example, the lower electrodes LE1, LE2, and LE3 correspond to anodes, and the upper electrodes UE1, UE2, and UE3 correspond to cathodes

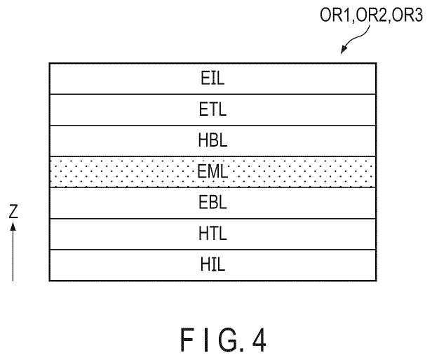

FIG. 4 is a diagram showing an example of a layer structure that can be applied to the organic layers OR1, OR2, and OR3. The organic layers OR1, OR2, and OR3 are each constituted by a plurality of thin films including the emitting layer EML.

In this embodiment, it is assumed that the organic layers OR1, OR2, OR3 have such a configuration that a hole injection layer HIL, a hole transport layer HTL, an electron blocking layer EBL, an emitting layer EML, a hole blocking layer HBL, an electron transport layer ETL and an electron injection layer EIL are stacked in this order along the Z direction. However, the organic layers OR1, OR2, and OR3 may as well have some other configuration such as the so-called tandem structure including multiple emitting layers EML.

The cap layers CP1, CP2, and CP3 (shown in FIG. 3) have, for example, a stacked layer structure in which multiple transparent layers are stacked one on another. These transparent layers may include layers formed form inorganic materials and layers formed from organic materials. In addition, these transparent layers have refractive indices different from each other.

For example, the refractive indices of these transparent layers are different from the refractive indices of the upper electrodes UE1, UE2, and UE3 and the sealing layers SE1, SE2, and SE3. Note that at least one of the cap layers CP1, CP2, and CP3 may be omitted.

The bottom layer 63 and the axial layer 64 (shown in FIG. 3) of the partition 6 are formed from metal materials. For the metallic material of the bottom layer 63, for example, molybdenum, titanium, titanium nitride (TiN), molybdenum-tungsten alloy (MoW) or molybdenum-niobium alloy (MoNb) can be used.

For the metal material for the axial layer 64, for example, aluminum, aluminum-neodymium alloy (AlNd), aluminum-yttrium alloy (AlY), or aluminum-silicon alloy (AlSi) can be used. Note here that the axis layer 64 may as well be formed of an insulating material.

For example, the upper portion 62 of the partition 6 has a stacked layer structure constituted by a lower layer formed of a metal material and an upper layer formed of a conductive oxide. For the metal material of the lower layer, for example, titanium, titanium nitride, molybdenum, tungsten, molybdenum-tungsten alloy or molybdenum-niobium alloy can be used. For the conductive oxide material of the upper layer, for example, ITO or IZO can be used. Note that the upper portion 62 may have a single layer structure of a metal material. Further, the upper portion 62 may include a layer formed of an insulating material.

To the partition 6, a common voltage is supplied. This common voltage is supplied to each of the upper electrodes UE1, UE2, and UE3, which are in contact with the side surfaces of the lower portion 61. To the lower electrodes LE1, LE2, and LE3, a pixel voltage corresponding to the video signal of the signal lines SL are supplied via the pixel circuits 1 of the subpixels SP1, SP2, and SP3, respectively.

The organic layers OR1, OR2, and OR3 emit light in response to the application of voltage. More specifically, when a potential difference is created between the lower electrode LE1 and the upper electrode UE1, the emitting layer EML of the organic layer OR1 emits light of a wavelength range of blue color. When a potential difference is created between the lower electrode LE2 and the upper electrode UE2, the emitting layer EML of the organic layer OR2 emits light of a wavelength range of green color. When a potential difference is created between the lower electrode LE3 and the upper electrode UE3, the emitting layer EML of the organic layer OR3 emits light of a wavelength range of red color.

As another example, the emitting layers EML of the organic layers OR1, OR2, and OR3 may emit light of the same color (for example, white). In this case, the display device DSP may comprise color filters that convert the light emitted by the emitting layer EML into light of colors corresponding to the subpixels SP1, SP2, and SP3, respectively. Further, the display device DSP may comprise layers containing quantum dots that are excited by the light emitted by the emitting layer EML to generate light of colors corresponding to the subpixels SP1, SP2, and SP3, respectively.

The circuit layer 11, the insulating layer 12, and the inorganic insulating layer 5 shown in FIG. 3 are arranged over the display area DA and the peripheral area SA.

Next, a motherboard 100 for display devices, for manufacturing a plurality of display devices DSP in a batch will now be described.

FIG. 5 is a plan view showing an example of the motherboard 100 for display devices. The motherboard 100 for display devices comprises a plurality of panel portions PP and a margin portion MP on an outer side of each of the plurality of panel portions PP on a large-scale substrate 10.

In this embodiment, the shape of the large-scale substrate 10 in plan view is rectangular. Note here that the shape of the large substrate 10 in plan view is not limited to rectangular, but it may be some other shape such as a square, circle or oval.

A plurality of panel portions PP are arranged in a matrix along the X direction and the Y direction. Each of the panel portions PP is removed by cutting the display device motherboard 100 along a cut line (not shown).

Each of the removed panel portions PP corresponds to the display panel PNL of the display device DSP shown in FIG. 1. In the margin portion MP, a plurality of pads PD, which are electrically connected to a test element group, for example, and window portions WP are arranged.

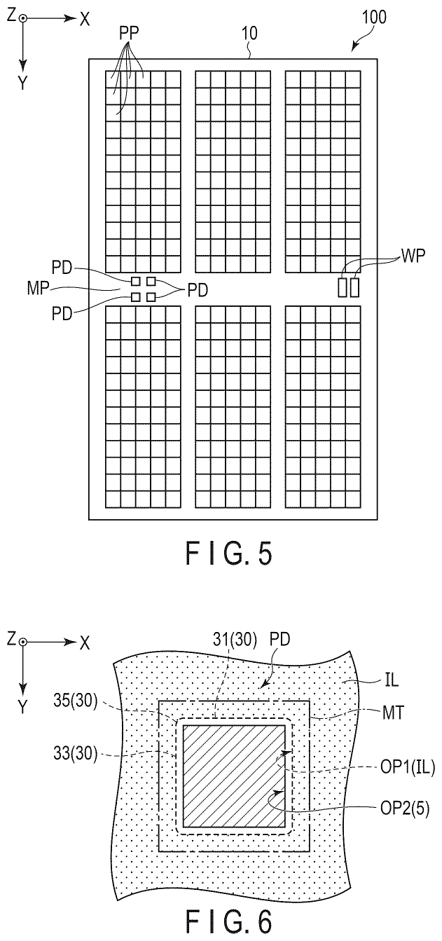

FIG. 6 is a plan view showing one configuration example of the pads PD. The pads PD shown in FIG. 6 corresponds to the pads PD in the peripheral area SA shown in FIG. 1 or the pads PD in the margin portion MP shown in FIG. 5.

The inorganic insulating layer 5 (shown in FIG. 3) is placed on an organic insulating layer IL. The organic insulating layer IL includes at least the insulating layer 12 shown in FIG. 3. The organic insulating layer IL and the inorganic insulating layer 5 are disposed on each of the panel portions PP and also over the margin portion MP. When the panel portions PP are focused, the organic insulating layer IL and the inorganic insulating layer 5 are arranged over the display area DA and the peripheral area SA.

In the peripheral area SA and the margin portion MP, the organic insulating layer IL has an aperture OP1 and the inorganic insulating layer 5 has an aperture OP2. The aperture OP1 is indicated by a dotted line and the aperture OP2 is indicated by a solid line.

The circuit layer 11 (shown in FIG. 3) includes a metal layer MT. The metal layer MT, shown by a single dotted line, corresponds to an electrode of each pad PD. The metal layer MT overlaps the aperture OP1 of the organic insulating layer IL and the aperture OP2 of the inorganic insulating layer 5. The portion of the organic insulating layer IL, which does not overlap the aperture OP1 is marked with dots.

The area of the aperture OP2 is smaller than that of the aperture OP1 in plan view. The portion of the metal layer MT, which is exposed from the aperture OP1 and the aperture OP2 is indicated by shaded lines. The peripheral portion of the metal layer MT is covered by the organic insulating layer IL and the inorganic insulating layer 5.

The apertures OP1 and OP2 have respective quadrilateral shapes in plan view, for example. The quadrilateral shapes include a rectangular shape, a square shape, a rhombus shape, a trapezoid shape, a parallelogram shape, and the like. As an example, the apertures OP1 and OP2 have respective square shapes in plan view. The length of the aperture OP1 along each of the X direction and the Y direction is, for example, about 400 μm, but it is not limited to that of this example.

The aperture OP1 has an edge 30, as shown in FIG. 6. The edge 30 of the aperture OP1 is formed into a step-like portion. The edge 30 includes a pair of edges 31 (first edges) extending along the X direction, a pair of edges 33 (second edges) extending along the Y direction, and round portions 35. The round portion 35 is an example of a corner portion that connects an edge 31 and a respective edge 33 with each other. The edge 30 has four round portions 35.

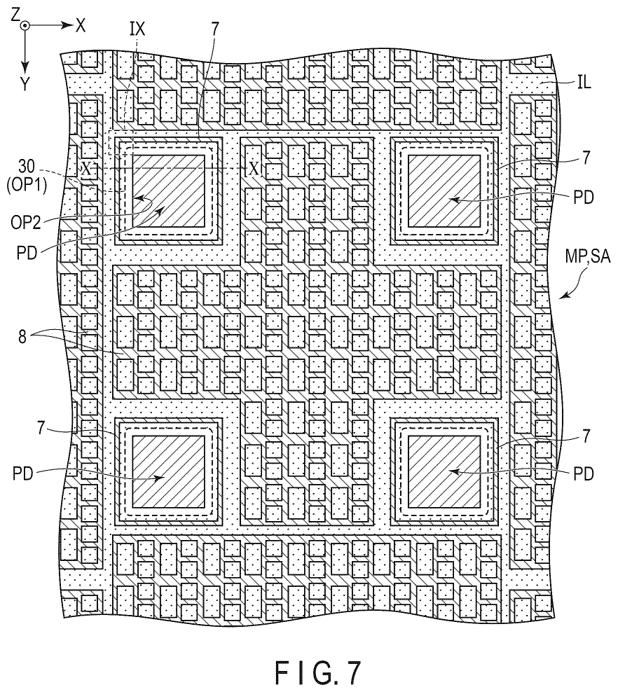

FIG. 7 is a plan view showing a configuration example of a region including the pads PD in the peripheral area SA or the margin portion MP. In the example shown in FIG. 7, four pads PD are provided. The metal layer MT of each of the pads PD is exposed from the respective apertures OP1 and OP2.

The motherboard 100 for display device (display device DSP) further comprises a conductive partition 7 (second partition) and a conductive partition 8. The partitions 7 and 8 are disposed above the organic insulating layer IL in the peripheral area SA or the margin portion MP. The partition 7 is disposed along the edge 30 of the aperture OP1 on an outer side of the aperture OP1. The partition 7 surrounds the aperture OP1, for example.

The partition 8 is disposed in a cross-shaped region between each respective pair of the four pads PD. The partition 8 is disposed in the region around the four pads PD as well. The partitions 8 are formed into a grid shape in the example shown in FIG. 7. The partition 8 is formed into a pattern similar to that of the lattice-shaped partition 6 shown in FIG. 2, for example. Further, the partitions 7 and 8 are not formed in the region which overlaps the aperture OP1.

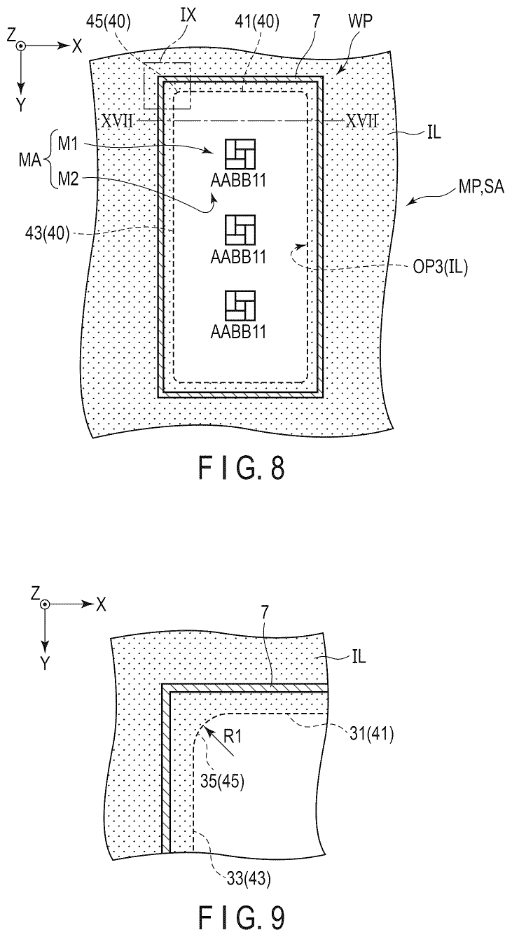

FIG. 8 is a plan view showing a configuration example of a region including the window portions WP in the peripheral area SA or the margin portion MP. In the example shown in FIG. 8, an area containing one window portion WP is shown.

The organic insulating layer IL has an aperture OP3. The window portion WP is formed as that the organic insulating layer IL has the aperture OP3. In FIG. 8, the aperture OP3 is shown by a dotted line. The portion of the organic insulating layer IL, which does not overlap the aperture OP3 is marked with dots.

The aperture OP3 has, for example, a quadrilateral shape in plan view. As an example, the aperture OP3 has a rectangular shape with long sides along the Y direction in plan view.

The aperture OP3 has an edge 40, as shown in FIG. 8. The edge 40 includes a pair of edges 41 (first edges) extending in the X direction, a pair of edges 43 (second edges) extending in the Y direction, and round portions 45 each connecting the respective edges 41 and 43 with each other. The round portion 45 is an example of a corner portion connecting the respective edges 41 and 43. The edge 40 includes four round portions 45.

In the window portion WP, a plurality of (for example, three) marks MA are disposed in the region that overlaps the aperture OP3. The marks MA are, for example, marks used in the manufacturing process to improve accuracy.

The marks MAs are formed, for example, by metal layers included in the circuit layer 11 (shown in FIG. 3). The marks MA are each formed by combining figures, letters, symbols and the like. The marks MA include, for example, a mark M1 formed by graphical figures and a mark M2 formed by letters. Note that the marks MA are not limited to these of this example.

On an outer side of the aperture OP3, a partition 7 is provided in a manner similar to that of the aperture OP1. That is, the partition 7 is disposed along the edge 40 of the aperture OP3 on an outer side of the aperture OP3. The partition 7 surrounds the aperture OP3, for example. Further, the partition 7 is not formed in the region that overlaps the aperture OP3.

FIG. 9 is a partial enlarged view schematically showing a part IX shown in FIGS. 7 and 8. In FIG. 9, a region including one of the plurality of round portions 35, 45 is shown, but the configuration of the region including other round portions 35, 45 is similar to that shown in FIG. 9.

The round portions 35 and 45 each have an arc shape in plan view, as shown in FIG. 9. In other words, the round portions 35 and 45 have a radius of curvature R1. The radius of curvature R1 of the round portions 35 and 45 is greater than, for example, the thickness of the organic insulating layer IL. The radius of curvature R1 of the round portions 35 and 45 should preferably be, for example, 25 μm or more.

As described above, the partition 7 is disposed along the edges 30 and 40 of the apertures OP1 and OP3. When the round portions 35 and 45 is focused, at least a part of the partition 7 is disposed on an outer side of each of the round portions 35 and 45 (corner portions).

When the aperture OP1 is focused, the partition 7 is disposed on an outer side of the round portion 35 and also on outer side of each of the edges 31 and 33. When the aperture OP3 is focused, the partition 7 is disposed on an outer side of the round portion 45 and also on an outer side of each of the edges 41 and 43.

Next, a configuration example of the display device motherboard 100 having an aperture OP1 will be described.

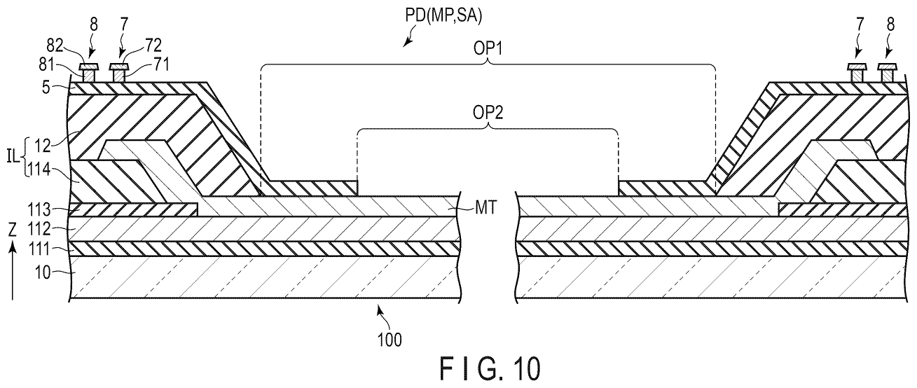

FIG. 10 is a cross-sectional view schematically showing the display device motherboard 100 taken along the line X-X line in FIG. 7. The circuit layer 11 (shown in FIG. 3) includes an insulating layer 111, a wiring layer 112, an insulating layer 113, an insulating layer 114, and a metal layer MT.

The insulating layer 111 is an inorganic insulating layer and is disposed on the substrate 10. The wiring layer 112 is disposed on the insulating layer 111. The insulation layer 113 is an inorganic insulating layer and is disposed on the wiring layer 112.

The wiring layer 112 is exposed from the insulating layer 113 in the respective pad PD. The insulating layer 114 is an organic insulating layer and is disposed on the insulating layer 113. The metal layer MT is disposed on the insulating layer 113 and the insulating layer 114 and is brought into contact with the wiring layer 112 in the respective pad PD.

With this configuration, the metal layer MT is electrically connected to the wiring layer 112. The insulating layer 111, the wiring layer 112, the insulating layer 113, the insulating layer 114 and the metal layer MT are included in the circuit layer 11 shown in FIG. 3. Note that in addition to the layers shown in the figure, the circuit layer 11 may further include an insulating layer and a conductive layer.

The insulating layer 12 is an organic insulating layer and is disposed on the insulating layer 114 and the metal layer MT. The organic insulating layer IL described above includes the insulating layer 114 and the insulating layer 12. That is, the organic insulating layer IL is disposed above the substrate 10. The insulating layer 12 has an aperture OP1 that exposes the metal layer MT. The aperture OP1 corresponds to an aperture in the organic insulating layer IL.

The inorganic insulating layer 5 covers the insulating layer 12 and is in contact with the metal layer MT. The inorganic insulating layer 5 has an aperture OP2 that overlaps the aperture OP1. The metal layer MT is exposed from the inorganic insulating layer 5 in the aperture OP2.

The partitions 7 and 8 are disposed above the organic insulating layer IL. The partitions 7 and 8 each include conductive lower portion 71 and 81 disposed on the inorganic insulating layer 5 and upper portions 72 and 82 disposed on the lower portion 71 and 81, respectively. The upper portions 72 and 82 have widths greater than those of the lower portions 71 and 81, respectively.

Both end portions of each of the upper portions 72 and 82 protrude from the respective side surfaces of the respective one of the lower portions 71 and 81, respectively. Thus, the partitions 7 and 8 are overhanging, as in the case of the partition 6 shown in FIG. 3. The lower portions 71 and 81 each may have a bottom layer disposed on the inorganic insulating layer 5 and an axial layer disposed on the bottom layer, as in the case of the partition 6 shown in FIG. 3.

The partitions 7 and 8 can be formed by the same process as that for the partition 6. In this case, the lower portions 71 and 81 are formed of the same material as that of the lower portion 61 and the upper portions 72 and 82 are formed of the same material as that of the upper portion 62.

Next, another configuration example of the cross-sectional structure of the display device motherboard 100 that includes an aperture OP1 will be described.

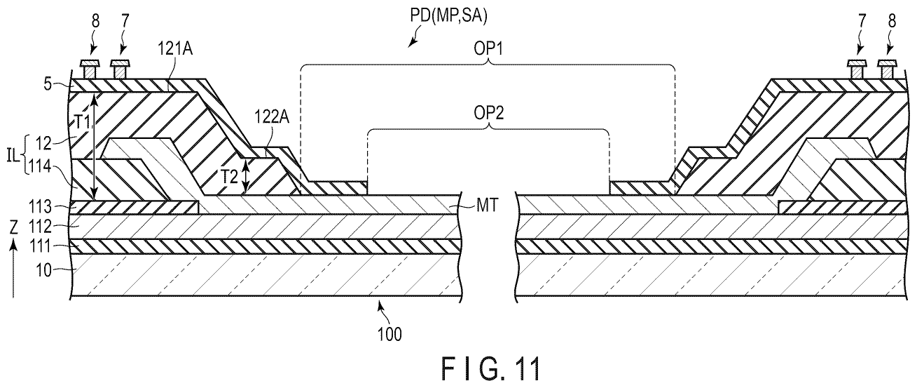

FIG. 11 is a cross-sectional view schematically showing another configuration example of the display device motherboard 100. The configuration example shown in FIG. 11 is different from the configuration example shown in FIG. 10 in that the organic insulating layer IL has a step-shaped cross-section.

The organic insulating layer IL includes an insulating layer 114 and an insulating layer 12. The insulating layer 12 has an aperture OP1. When the cross-sectional shape of the organic insulating layer IL is focused, the organic insulating layer IL has a step-shaped cross-section whose thickness decreases toward the aperture OP1.

A thickness T1 of the organic insulating layer IL is the sum of the thickness of the insulating layer 114 and the thickness of the insulating layer 12, and corresponds to the distance along the Z direction from the upper surface of the insulating layer 113 to the substantially flat upper surface 121A of the insulating layer 12.

A thickness T2 of the organic insulating layer IL is the thickness of the insulating layer 12 between the insulating layer 114 and the aperture OP1, and corresponds to the distance along the Z direction from the upper surface of the metal layer MT to the substantially flat upper surface 122A of the insulating layer 12. The thickness T2 is less than the thickness T1. The upper surface 122A is located between the upper surface 121A and the aperture OP1. The upper surface 122A is located lower than the upper surface 121A.

The partitions 7 and 8 are located on the inorganic insulating layer 5 and above the organic insulating layer IL. In the example shown in FIG. 11, the partition 7 is disposed above the upper surface 121A, while it is not disposed above the upper surface 122A. Note here that the partition 7 may as well be disposed above the upper surface 122A.

The organic insulating layer IL having a step-shaped cross-section can be formed, for example, by a technique which will be described. First, an insulating layer 114 is formed on the insulating layer 113. Then, a metal layer MT is formed. After that, an insulating layer 12 having an apertures OP1, an upper surface 121A, and a lower surface 122A is formed.

The insulating layer 12 having such a configuration can be formed by, for example, the below-described method. On an entire surface of the display device motherboard 100 on which the metal layer MT is formed, an insulating film is formed using, for example, a positive organic material. After that, the insulating layer is exposed. In this exposure process, the amount of exposure of the aperture OP1 is set to the maximum and the exposure amount is set to decrease in steps as the location approaches outward from the aperture OP1. Then, the exposed insulating layer is developed. Subsequently, the insulating layer is then fired. With this operation, an organic insulating layer IL having the cross-sectional shape described above is formed.

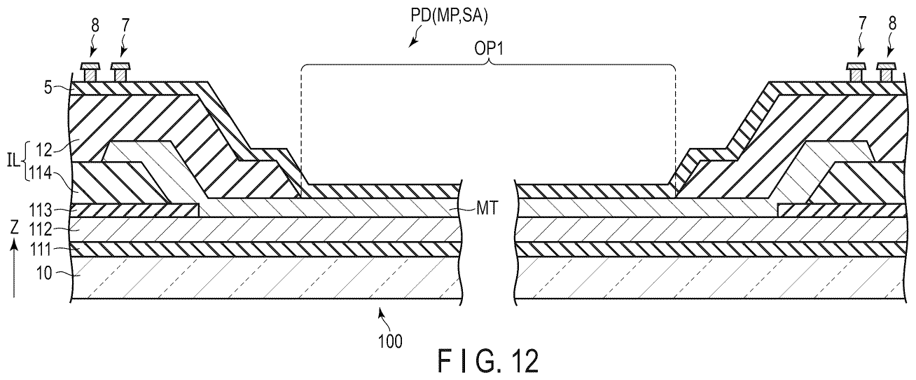

FIG. 12 is a cross-sectional view schematically showing still another configuration example of the display device motherboard 100. The configuration example shown in FIG. 12 is different from the configuration example shown in FIG. 11 in that the inorganic insulating layer 5 has no apertures. The inorganic insulating layer 5 covers the insulating layer 12 and also covers the metal layer MT exposed from the aperture OP1. In other words, the metal layer MT is not exposed.

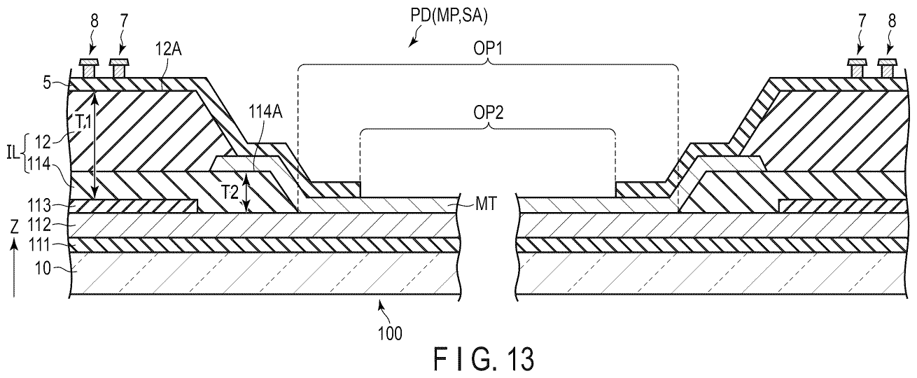

FIG. 13 is a cross-sectional view schematically showing still another configuration example of the display device motherboard 100. The configuration example shown in FIG. 13 is different from the configuration example shown in FIG. 11 in that the insulating layer 114 extends toward the pad PD more than the insulating layer 12. The insulating layer 114 has an aperture OP1. When the cross-sectional shape of the organic insulating layer IL is focused, the organic insulating layer IL has a step-shaped cross-section whose thickness decreases toward the aperture OP1.

The thickness T1 of the organic insulating layer IL is the sum of the thickness of the insulating layer 114 and the thickness of the insulating layer 12, and corresponds to the distance along the Z direction from the upper surface of the insulating layer 113 to the substantially flat upper surface 12A of the insulating layer 12. The thickness T2 of the organic insulating layer IL is the thickness of the insulating layer 114 between the insulating layer 12 and the aperture OP1, and corresponds to the distance along the Z direction from the upper surface of the wiring layer 112 to the substantially flat upper surface 114A of the insulating layer 114. The thickness T2 is less than the thickness T1. The upper surface 114A is located between the upper surface 12A and the aperture OP1. The upper surface 114A is located lower than the upper surface 12A.

The partition 7 is disposed above the upper surface 12A in the example shown in FIG. 13, while it is not disposed above the upper surface 114A. Note here that the partition 7 may be disposed above the upper surface 114A.

The organic insulating layer IL having a step-shaped cross-section can be formed, for example, by the following method. First, an insulating layer 114 having an aperture OP1 and an upper surface 114A is formed on the insulating layer 113. Then, a metal layer MT is formed. After that, an insulating layer 12 having an upper surface 12A is formed. With this operation, the organic insulating layer IL having the cross-sectional shape described above is formed.

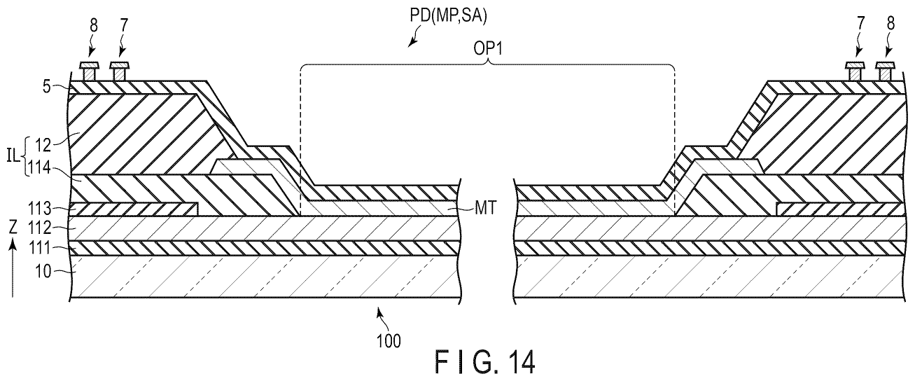

FIG. 14 is a cross-sectional view schematically showing still another configuration example of the display device motherboard 100. The configuration example shown in FIG. 14 is different from the configuration example shown in FIG. 13 in that the inorganic insulating layer 5 has no apertures.

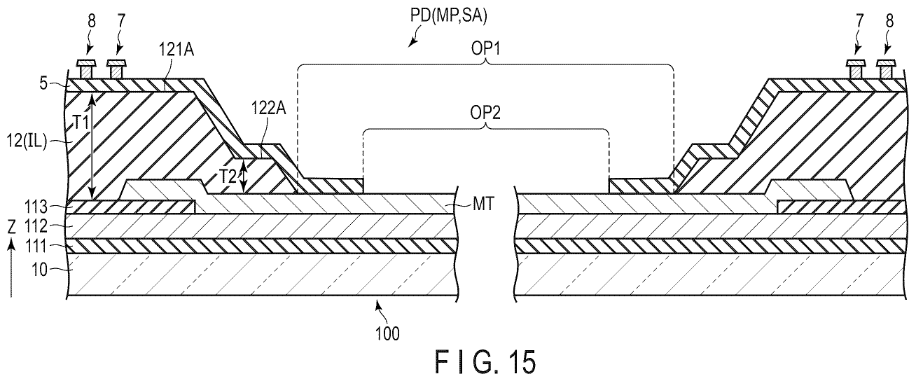

FIG. 15 is a cross-sectional view schematically showing still another configuration example of the display device motherboard 100. The configuration example shown in FIG. 15 is different from the configuration example shown in FIG. 11 in that the organic insulating layer IL having a step-shaped cross-section is a single layer of an insulating layer 12. In other words, the organic insulating layer IL does not have the insulating layer 114. The insulating layer 12 has an aperture OP1.

The thickness T1 of the organic insulating layer IL corresponds to the distance along the Z direction from the upper surface of the insulating layer 113 to the substantially flat upper surface 121A of the insulating layer 12. The thickness T2 of the organic insulating layer IL corresponds to the distance along the Z direction from the upper surface of the metal layer MT to the substantially flat upper surface 122A of the insulating layer 12. The thickness T2 is less than the thickness T1. The upper surface 122A is located between the upper surface 121A and the aperture OP1. The upper surface 122A is located lower than the upper surface 121A.

The partitions 7 and 8 are located on the organic insulating layer IL above the inorganic insulating layer 5. In the example shown in FIG. 15, the partition 7 is disposed above the upper surface 121A, while it is not disposed above the upper surface 122A. Note that the partition 7 may be disposed above the upper surface 122A.

The insulating layer 12 can be formed, for example, by the following technique. An insulating layer is formed on the entire surface of the display device motherboard 100 on which the metal layer MT is formed, using, for example, a positive organic material. The insulating layer is then exposed. In this exposure process, the amount of exposure of the aperture OP1 is set to the maximum and the exposure amount is set to decrease in steps as the location approaches outward from the aperture OP1. Then, the exposed insulating layer is developed. After that, the insulating layer is fired. With this operation, the insulating layer 12 (organic insulating layer IL) having the cross-sectional shape described above is formed.

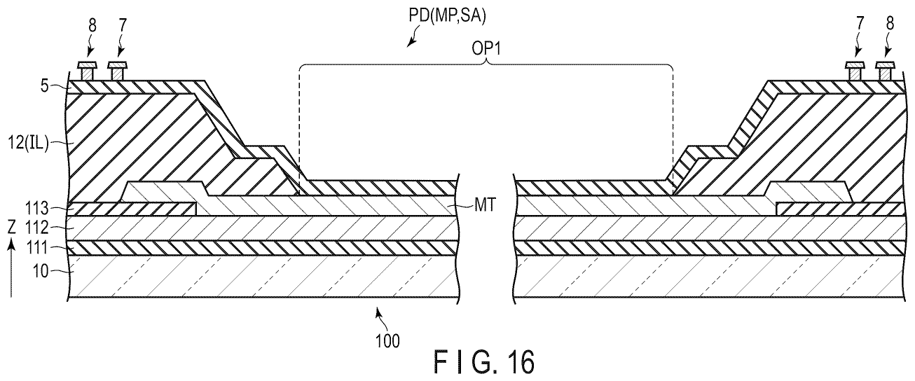

FIG. 16 is a cross-sectional view schematically showing still another configuration example of the display device motherboard 100. The configuration example shown in FIG. 16 is different from the configuration example shown in FIG. 15 in that the inorganic insulating layer 5 has no apertures.

The configuration example of the display device motherboard 100 having the apertures OP3 will now be described.

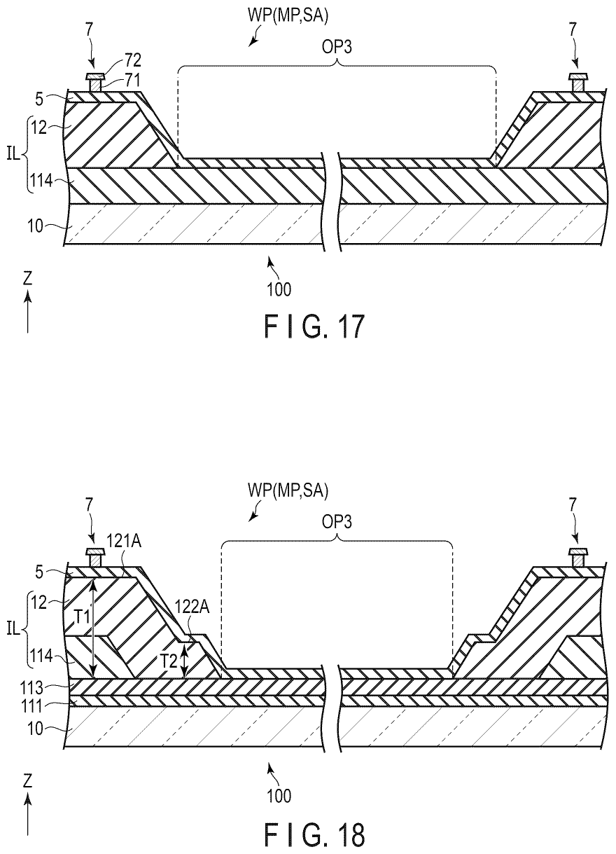

FIG. 17 is a cross-sectional view schematically showing the display device motherboard 100 taken along the line XVII-XVII in FIG. 8. The insulating layer 114 is disposed on the substrate 10. The insulating layer 12 is disposed on the insulating layer 114. The insulating layer 12 has an aperture OP3 that exposes the insulating layer 114. In other words, the insulating layer 114 does not have an aperture at the position that overlaps the aperture OP3.

The organic insulating layer IL described above includes the insulating layer 114 and the insulating layer 12. The aperture OP3 corresponds to an aperture of the organic insulating layer IL. The inorganic insulating layer 5 covers the insulating layer 12 and is in contact with the insulating layer 114 in the aperture OP3.

The partition 7 is disposed above the organic insulating layer IL. The partition 7 includes a lower portion 71 disposed on the inorganic insulating layer 5 and an upper portion 72 disposed on the lower portion 71. The upper portion 72 has a width larger than that of the lower portion 71.

Next, another example of the cross-sectional structure of the display device motherboard 100 including a window portion WP will be described.

FIG. 18 is a schematic cross-sectional view of another configuration example of the display device motherboard 100. The configuration example shown in FIG. 18 is different from the configuration example shown in FIG. 17 in that the insulating layer 111 and the insulating layer 113 are provided and the insulating layer 114 is opened.

The insulating layer 111 is disposed on the substrate 10. The insulating layer 113 is disposed on the insulating layer 111. The insulating layer 114 is disposed on the insulating layer 113. The insulating layer 12 covers the insulating layer 114 and has an aperture OP3 in the region in contact with the insulating layer 113. In other words, the insulating layer 114 has an aperture at a position that overlaps the aperture OP3.

In the example shown in FIG. 18, the organic insulating layer IL has a cross-sectional shape similar to that of the organic insulating layer IL shown in FIG. 11. The thickness T1 of the organic insulating layer IL is the sum of the thickness of the insulating layer 114 and the thickness of the insulating layer 12, and corresponds to the distance along the Z direction from the upper surface of the insulating layer 113 to the substantially flat upper surface 121A of the insulating layer 12.

The thickness T2 of the organic insulating layer IL is the thickness of the insulating layer 12 and corresponds to the distance along the Z direction from the upper surface of the insulating layer 113 to the substantially flat upper surface 122A of the insulating layer 12. The thickness T2 is less than the thickness T1. The upper surface 122A is located between the upper surface 121A and the aperture OP3. The upper surface 122A is located lower than the upper surface 121A.

The inorganic insulating layer 5 covers the insulating layer 12 and covers the insulating layer 113 in the aperture OP3. The partition 7 is located above the organic insulating layer IL. In the example shown in FIG. 18, the partition 7 is disposed above the upper surface 121A, while it is not disposed above the upper surface 122A. Note that the partition 7 may be disposed above upper surface 122A.

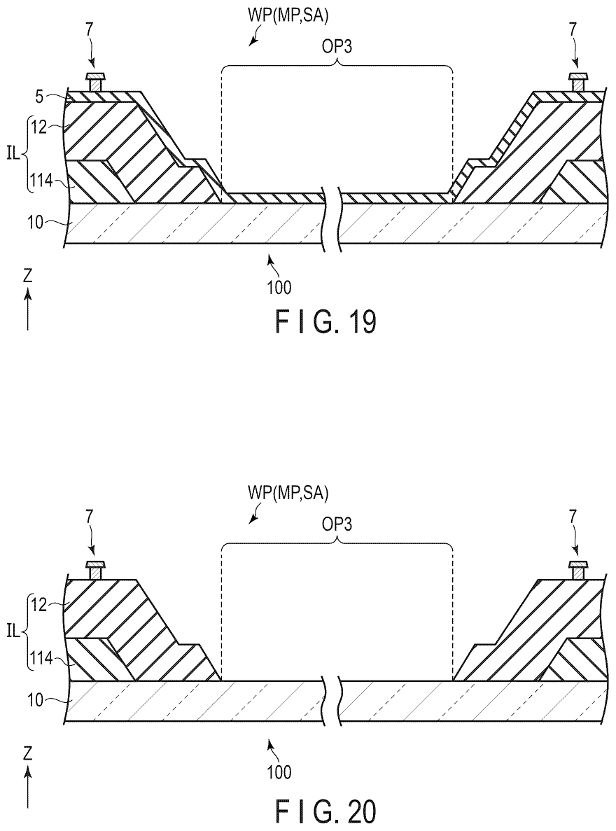

FIG. 19 is a cross-sectional view schematically showing still another configuration example of the display device motherboard 100. The configuration example shown in FIG. 19 is different from the configuration example shown in FIG. 18 in that the insulating layer 111 and the insulating layer 113 are omitted.

The insulating layer 114 is disposed on the substrate 10. The insulating layer 12 covers the insulating layer 114 and has an aperture OP3 in the region in contact with the substrate 10. The inorganic insulating layer 5 covers the substrate 10 in the aperture OP3.

FIG. 20 is a cross-sectional view schematically showing still another configuration example of the display device motherboard 100. The configuration example shown in FIG. 20 is different from the configuration example shown in FIG. 19 in that the inorganic insulating layer 5 is omitted. The partition 7 is disposed on the insulating layer 12.

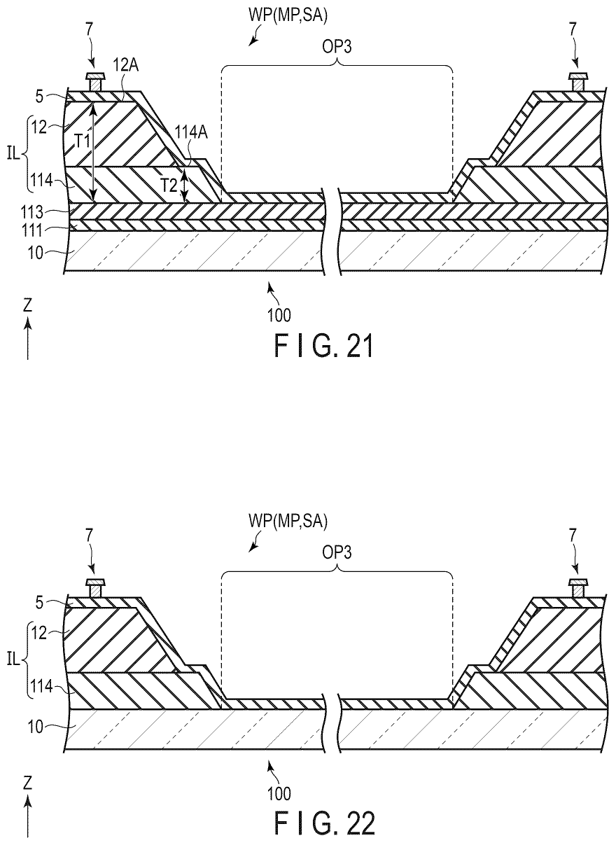

FIG. 21 is a cross-sectional view schematically showing still another configuration example of the display device motherboard 100. The configuration example shown in FIG. 20 is different from the configuration example shown in FIG. 18 in that the insulating layer 114 extends toward the center of the aperture OP3 further more than the insulating layer 12. The insulating layer 114 has the aperture OP3.

In the example shown in FIG. 21, the organic insulating layer IL has a cross-sectional shape similar to that of the organic insulating layer IL shown in FIG. 13. The thickness T1 of the organic insulating layer IL is the sum of the thickness of the insulating layer 114 and the thickness of the insulating layer 12, and corresponds to the distance along the Z direction from the upper surface of the insulating layer 113 to the substantially flat upper surface 12A of the insulating layer 12.

The thickness T2 of the organic insulating layer IL is the thickness of the insulating layer 114 exposed from the insulating layer 12 and corresponds to the distance along the Z direction from the upper surface of the insulating layer 113 to the substantially flat upper surface 114A of the insulating layer 114. The thickness T2 is less than the thickness T1. The upper surface 114A is located between the upper surface 12A and the aperture OP3. The upper surface 114A is located lower than the upper surface 12A.

The inorganic insulating layer 5 covers the insulating layer 12, covers the insulating layer 114 exposed from the insulating layer 12, and covers the insulating layer 113 in the aperture OP3. The partition 7 is disposed above the organic insulating layer IL. In the example shown in FIG. 20, the partition 7 is disposed above the upper surface 12A, while it is not disposed above the upper surface 114A. Note that the partition 7 may be disposed above upper surface 114A.

FIG. 22 is a cross-sectional view schematically showing still another configuration example of the display device motherboard 100. The configuration example shown in FIG. 22 is different from the configuration example shown in FIG. 21 in that the insulating layer 111 and the insulating layer 113 are omitted. The insulating layer 114 is disposed on the substrate 10 and has an aperture OP3. The inorganic insulating layer 5 covers the substrate 10 in the aperture OP3.

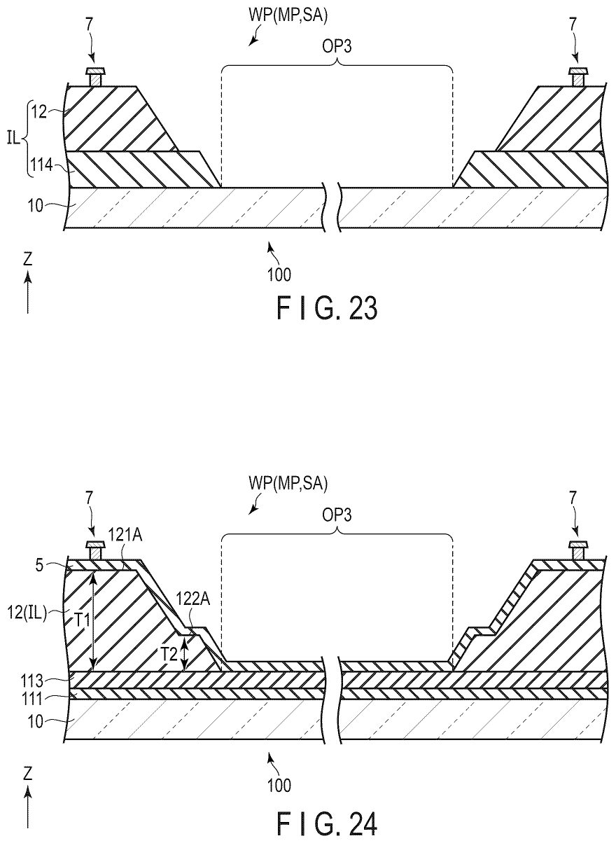

FIG. 23 is a cross-sectional view schematically showing still another configuration example of the display device motherboard 100. The configuration example shown in FIG. 23 is different from the configuration example shown in FIG. 22 in that the inorganic insulating layer 5 is omitted. The partition 7 is disposed on the insulating layer 12.

FIG. 24 is a cross-sectional view schematically showing still another configuration example of the display device motherboard 100. The configuration example shown in FIG. 24 is different from the configuration example shown in FIG. 18 in that the organic insulating layer IL having a step-shaped cross-section is a single layer of the insulating layer 12. In other words, the organic insulating layer IL does not have the insulating layer 114. The insulating layer 12 has an aperture OP3.

In the example shown in FIG. 24, the organic insulating layer IL has a cross-sectional shape similar to that of the organic insulating layer IL shown in FIG. 15. The thickness T1 of the organic insulating layer IL corresponds to the distance along the Z direction from the upper surface of the insulating layer 113 to the substantially flat upper surface 121A of the insulating layer 12.

The thickness T2 of the organic insulating layer IL corresponds to the distance along the Z direction from the upper surface of the insulating layer 113 to the substantially flat upper surface 122A of the insulating layer 12. The thickness T2 is less than the thickness T1. The upper surface 122A is located between the upper surface 121A and the aperture OP3. The upper surface 122A is located lower than the upper surface 121A.

The inorganic insulating layer 5 covers the insulating layer 12 and covers the insulating layer 113 in the aperture OP3. The partition 7 is located above the organic insulating layer IL. In the example shown in FIG. 24, the partition 7 is disposed above the upper surface 121A, while it is not disposed above the upper surface 122A. Note that the partition 7 may be disposed above upper surface 122A.

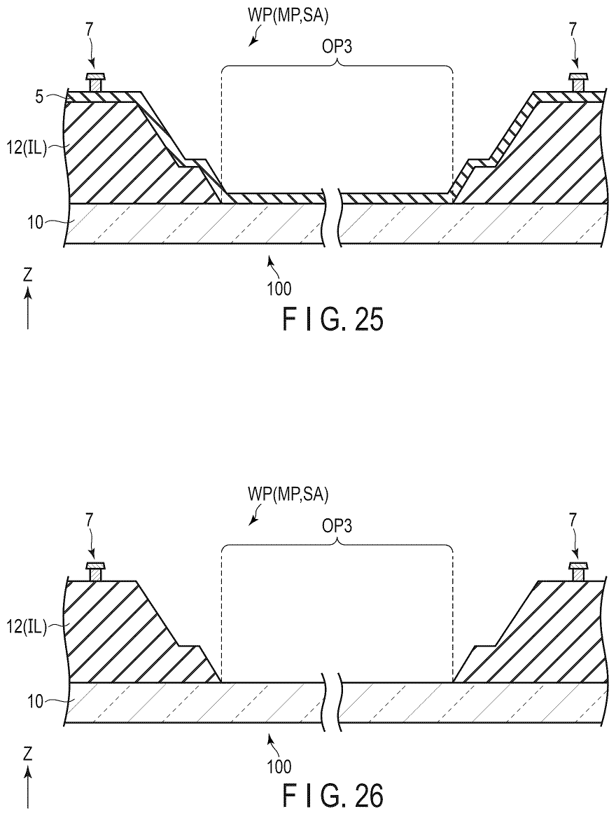

FIG. 25 is a cross-sectional view schematically showing still another configuration example of the display device motherboard 100. The configuration example shown in FIG. 25 is different from the configuration example shown in FIG. 24 in that the insulating layer 111 and the insulating layer 113 are omitted. The insulating layer 12 corresponding to the organic insulating layer IL is disposed on the substrate 10 and has an aperture OP3. The inorganic insulating layer 5 covers the substrate 10 in the aperture OP3.

FIG. 26 is a cross-sectional view schematically showing still another configuration example of the display device motherboard 100. The configuration example shown in FIG. 26 is different from the configuration example shown in FIG. 25 in that the inorganic insulating layer 5 is omitted. The insulating layer 12 corresponding to the organic insulating layer IL is disposed on the substrate 10 and has an aperture OP3. The partition 7 is disposed on the insulating layer 12.

With the display device DSP configured as described above, it is possible to improve the yield in the manufacturing process. More specifically, the display device motherboard 100 (display device DSP) comprises a partition 7 disposed along the edges 30 and 40 of the apertures OP1 and OP3 on respective outer sides of the apertures OP1 and OP3 in the peripheral area SA and the margin portion MP.

The multilayer films FL1, FL2, and FL3 (shown in FIG. 3), which are formed by vapor deposition, may peel off from the substrate during the manufacturing process of the display device DSP because they have weak adhesivity to the substrate. When such peeling expands, the multilayer films FL1, FL2, and FL3 and the sealing layers SE1, SE2, and SE3 provided respectively thereon may peel off, which may be a factor of contamination of the chambers and the like of the manufacturing line.

In this embodiment, the multilayer films FL1, FL2, and FL3 are divided by the overhanging partition 7. With this configuration, even if peeling off occurs in the multilayer films FL1, FL2, and FL3, its range does not easily expand. Further, the multilayer films FL1, FL2, and FL3 divided by the partition 7 are suppressed by the sealing layers SE1, SE2, and SE3 formed to enter under the upper portion 72 of the partition 7, thereby making it possible to make these films unlikely to peel off.

The multilayer films FL1, FL2, and FL3 are likely to peel off at the edges 30 and 40 of the apertures OP1 and OP3. More specifically, the multilayer films FL1, FL2, and FL3 are likely to peel off at a corner portion of the edges 30 and 40 of the apertures OP1 and OP3 as a starting point.

In this embodiment, the partition 7 surrounds at least part of the corner portions in the peripheral area SA and the margin portion MP. With this configuration, the peeling of the multilayer films FL1, FL2, and FL3 in the region which is lightly to become a starting point of peeling can be suppressed.

In this embodiment, the radius of curvature R1 of each of the round portions 35 and 45 is 25 μm or more. When each corner portion is right-angled in shape, the respective side surface of the organic insulating layer IL, which forms the corner portion is steeper than that of the edges 31 and 32.

With such a shape of the organic insulating layer IL, it is possible to cause creation of residues from the material constituting the partition 7, inside the aperture OP1 during the manufacturing process. Such residues can become a starting point and cause the multilayer films FL1, FL2, and FL3 to peel off easily. As the radius of curvature R1 of the round portions 35 and 45 is larger, it becomes less likely to generate residues. Some residues were actually observed in a range of the radius of curvature R1 of the round portions 35 and 45 of about 20 μm.

When the radius of curvature R1 is set to 25 μm or larger in the round portions 35 and 45, the shape of the side surfaces of the organic insulating layer IL in the round portions 35 and 45 can be made smooth. Thus, it becomes difficult that the above-described residues are generated in the manufacturing process. As a result, the round portions 35 and 45 are less likely to become a starting point for peeling off of the multilayer films FL1, FL2, and FL3.

As described above, according to the configuration of this embodiment, it is possible to suppress the peeling off of the multilayer films FL1, FL2, and FL3 and therefore to improve the yield in the manufacturing process. According to this embodiment, various other advantageous effects can be obtained as well.

Next, another example of the apertures OP1 and OP3 and the partition 7 in the peripheral area SA and the margin portion MP will be described. The following description will mainly focus on the region including the pads PD. Note that the configuration examples of the embodiments to be described below can each be applied to the region including the window portions WP as well. To the parts of the configurations in the embodiments to be provided, which are not specifically referred to, a configuration similar to that of the first embodiment can be applied.

### Second Embodiment

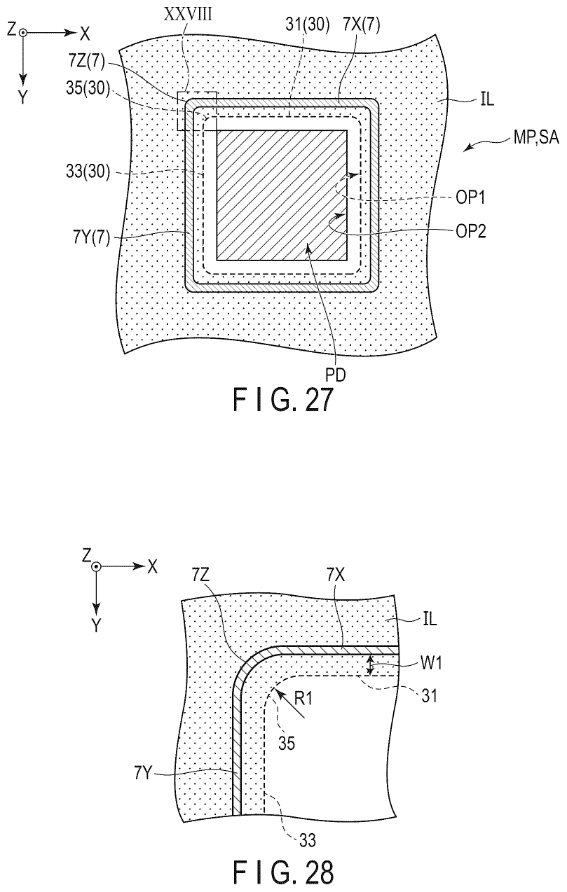

FIG. 27 is a plan view schematically showing the region including the pads PD in the peripheral area SA or the margin portion MP in this embodiment. FIG. 28 is an enlarged view of a part XXVIII in FIG. 27. The example shown in FIG. 27 is different in the shape of the partition 7 as compared to the configuration example shown in FIG. 7.

The partition 7 surrounds the aperture OP1 on an outer side of the aperture OP1, as shown in FIG. 27. The partition 7 includes a pair of partition portions 7X extending along the X direction, a pair of partition portions 7Y extending along the Y direction, and partition portions 7Z each connecting between the respectable one of the partition portions 7X and the respectable one of the partition portions 7Y.

The partition portions 7Z each have an arc shape in plan view, as shown in FIG. 28. The partition portion 7Z has a predetermined radius of curvature. When the round portion 35 is focused, the partition portion 7Z is disposed along the respective round portion 35.

The partition 7 is disposed at a certain distance apart from the edge 30 of the aperture OP1. More specifically, the partition portions 7X are each disposed at a certain distance apart from the respective edge 31, the partition portions 7Y are each disposed at a certain distance apart from the respective edge 33, and the partition portions 7Z are each disposed at a certain distance apart from the respective round portion 35. Note here that the distance is defined as the distance along a direction normal to the edge 30.

In other words, the partition 7 is disposed parallel to the edge 30 of the aperture OP1. In such a case, a distance W1 (shown in FIG. 28) from the edge 30 of the aperture OP1 to the partition 7 is approximately constant along the edge 30 of the aperture OP1.

In the configuration of this embodiment as well, advantageous effects similar to those of the first embodiment can be obtained. In this embodiment, the partition 7 is disposed at a certain distance apart from the edge 30 of the aperture OP1. More specifically, the distance between the partition portion 7Z of the partition 7 and the round portion 35 of the edge 30 is constant.

The peeling off of the multilayer films FL1, FL2, and FL3 is more likely to occur as the distance between the partition 7 and the edge 30 increases. When the partition 7Z is formed into an arc shape and the distance between the partition 7Z and the round portion 35 is made constant, the distance between the partition 7 and the edge 30 can be reduced compared to that of the first embodiment.

In this manner, it is possible to further suppress the peeling off of the multilayer films FL1, FL2, and FL3 at the corner portions, where the starting point of peeling can be easily made. Further, even if the peeling off occurs between the partition 7Z and the round portion 35, the partition 7 can suppress the expansion of the peeling and reduce the range of the peeling off. As a result, the yield rate in the manufacturing process can be improved.

### Third Embodiment

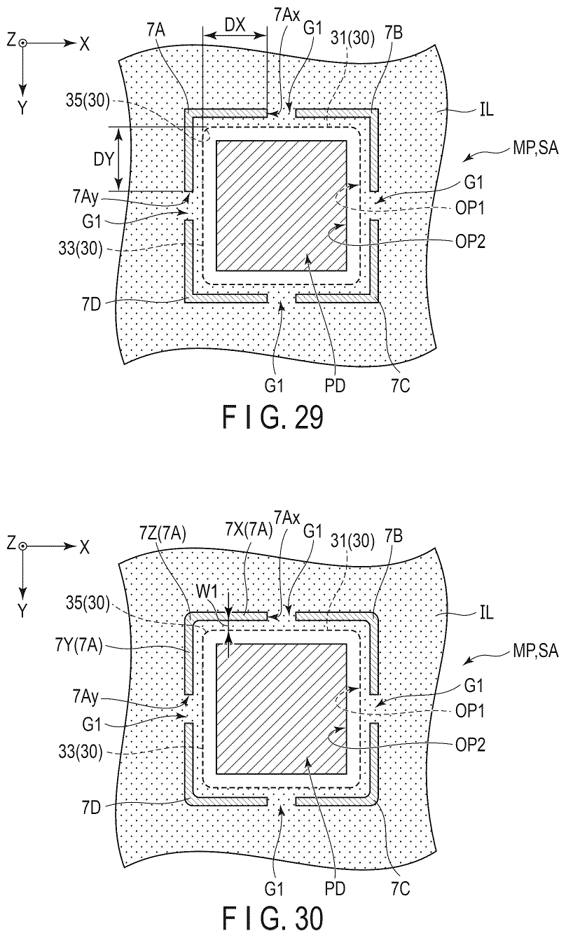

FIG. 29 is a plan view schematically showing the region including the pads PD in the peripheral area SA or the margin portion MP in this embodiment. The example shown in FIG. 29 is different from the configuration example shown in FIG. 7 in that the partition 7 includes a plurality of segments arranged at intervals. The partition 7 includes segments 7A, 7B, 7C, and 7D. The segments 7A, 7B, 7C, and 7D each have an L-letter shape.

The segments 7A, 7B, 7C, and 7D are each located on an outer side of the round portion 35. Gaps G1 are formed, respectively, between the segments 7A and 7B adjacent to each other along the X direction, between the segments 7C and 7D adjacent to each other along the X direction, between the segments 7A and 7D adjacent to each other along the Y direction, and between the segments 7B and 7C adjacent to each other along the Y direction.

When the segment 7A is focused, the segment 7A includes an end portion 7Ax opposing the segment 7B and an end portion 7Ay opposing the segment 7D. Here, as shown in FIG. 29, the distance between the edge 33 and end portion 7Ax along the X direction is defined as a distance DX, and the distance between the edge 31 and the end portion 7Ay along the Y direction is defined as a distance DY.

The segment 7A is formed so that the distance DX and the distance DY are at least 50 μm. In such a case, the segment 7A is located on an outer side of the round portion 35 and at least a part of the edges 31 of 33 connected to the round portion 35.

When the radius of curvature R1 of the round portion 35 (shown in FIG. 9) is 25 μm or more, the segment 7A should preferably be formed so that the distance DX and the distance DY are each 50 μm or more. Here, focusing on the segment 7A, the relationship thereof with respect to the aperture OP1 is explained. Note that segments 7B, 7C, and 7D are each formed into a configuration similar thereto.

In the configuration of this embodiment as well, advantageous effects similar to those of the first embodiment can be obtained. In this embodiment, the partition 7 comprises segments 7A, 7B, 7C, and 7D arranged spaced apart from each other at intervals.

If the partition 7 is not divided into a plurality of segments, some errors may be created in the formation of a resist (that is, a resist for patterning the inorganic insulating layer 5) disposed after the partition 7 in the manufacturing process.

In other words, the spreading of the resist is restrained by the partition 7, and such sites may be created that the resist is not sufficiently filled under the upper portion 72 of the partition 7. In this case, when the resist is dried under reduced pressure environment, the space where the resist is not placed may expand and rupture.

As in this embodiment, when the partition 7 is configured by a plurality of segments, the resist can easily spread through the gaps G1, and therefore it is possible to suppress defects in shape of the resist. As a result, the yield in the manufacturing process can be improved.

### Fourth Embodiment

FIG. 30 is a plan view schematically showing the region including the pads PD in the peripheral area SA or the margin portion MP in this embodiment. The example shown in FIG. 30 is different from the configuration example shown in FIG. 27 in that the partition 7 is constituted by a plurality of segments arranged at intervals.

The partition 7 includes segments 7A, 7B, 7C, and 7D. The segments 7A, 7B, 7C, and 7D each have an L-letter shape. The segments 7A, 7B, 7C, and 7D are each disposed on an outer side of the round portion 35.

Gaps G1 are formed, respectively, between the segments 7A and 7B adjacent to each other along the X direction, between the segments 7C and 7D adjacent to each other along the X direction, between the segments 7A and 7D adjacent to each other along the Y direction, and between the segments 7B and 7C adjacent to each other along the Y direction.

When the segment 7A is focused, the segment 7A includes a partition portion 7X extending along the X direction, a partition portion 7Y extending along the Y direction, and a partition portion 7Z connecting between the partition portion 7X and the partition portion 7Y. The partition portion 7Z has an arc shape in plan view. The partition portion 7Z has a predetermined radius of curvature.

The segment 7A is disposed at a certain distance from the edge 30 of the aperture OP1. The distance W1 from the edge 30 of the aperture OP1 to the segment 7A is constant along the edge 30 of the aperture OP1. Here, focusing on the segment 7A, the relationship thereof with respect to the aperture OP1 is explained. Note that segments 7B, 7C, and 7D are each formed into a configuration similar thereto.

The configuration of this embodiment is a combination of the configuration of the second embodiment described using FIG. 27 and the configuration of the third embodiment described using FIG. 29. In the configuration of this embodiment as well, advantageous effects similar to those of each of the embodiments provided above can be obtained.

### Fifth Embodiment

FIG. 31 is a plan view schematically showing the region including the pads PD in the peripheral area SA or the margin portion MP in this embodiment. The example shown in FIG. 31 is different from the configuration example shown in FIG. 7 in that the edge 30 of the aperture OP1 does not have a round portion.

Each of the corner portions 37 of the edge 30 is formed by connecting the respective edge 31 and the respective edge 33. The corner portions 37 each have a right-angle shape, as shown in FIG. 13. Here, the right-angle shape includes not only a 90-degree angle formed by the edges 31 and 33, but also variations in angle caused by the manufacturing process.

In the configuration of this embodiment as well, advantageous effects similar to those of the first embodiment can be obtained.

### Sixth Embodiment

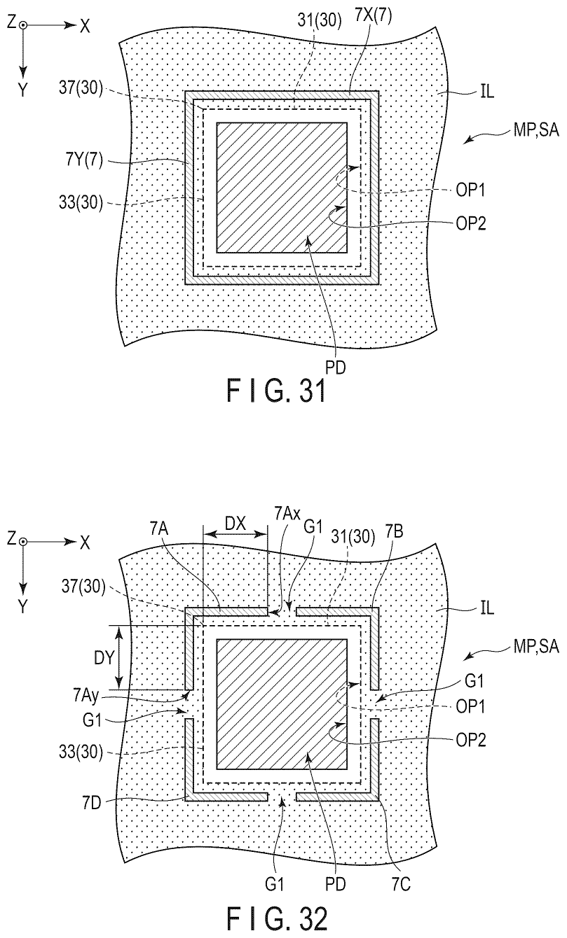

FIG. 32 is a plan view schematically showing the region including the pads PD in the peripheral area SA or the margin portion MP in this embodiment. The example shown in FIG. 32 is different from the configuration example shown in FIG. 31 in that the partition 7 is constituted by a plurality of segments arranged at intervals.

The partition 7 includes segments 7A, 7B, 7C, and 7D. The segments 7A, 7B, 7C, and 7D each have an L-letter shape. The segments 7A, 7B, 7C, and 7D are each arranged on an outer side of the corner portion 37.

Gaps G1 are formed, respectively, between the segments 7A and 7B adjacent to each other along the X direction, between the segments 7C and 7D adjacent to each other along the X direction, between the segments 7A and 7D adjacent to each other along the Y direction, and between the segments 7B and 7C adjacent to each other along the Y direction. When the segment 7A is focused, the segment 7A includes an end portion 7Ax opposing the segment 7B and an end portion 7Ay opposing the segment 7D.

When the corner portion 37 is right-angled, the segment 7A should preferably be formed so that the distance DX and the distance DY are each 100 μm or more. Not only when the corner portion 37 is a right-angle shape, but also when the radius of curvature R1 of the round portion 35 (shown in FIG. 9) is 25 μm or less, the segment 7A should preferably be formed so that the distance DX and the distance DY are each 100 μm or more.

Here, focusing on the segment 7A, the relationship thereof with respect to the aperture OP1 is explained. Note that segments 7B, 7C, and 7D are each formed into a configuration similar thereto.

The configuration of this embodiment is a combination of the configuration of the third embodiment described using FIG. 29 and the configuration of the fifth embodiment described using FIG. 31. In the configuration of this embodiment as well, advantageous effects similar to those of each of the embodiments provided above can be obtained.

### Seventh Embodiment

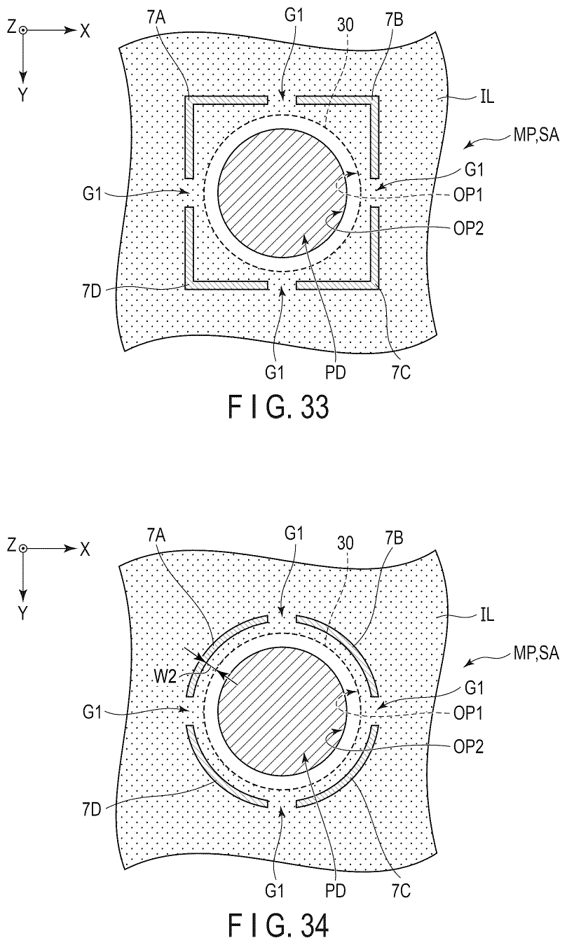

FIG. 33 is a plan view schematically showing the region including the pads PD in the peripheral area SA or the margin portion MP in this embodiment. The example shown in FIG. 33 is different from the configuration example shown in FIG. 29 in that the apertures OP1, OP2 each have a circular shape.

The apertures OP1 and OP2 each have a circular shape in plan view. In this embodiment, a part of the edge 30 of the aperture OP1 in the circumferential direction corresponds to the respective round portion of the aperture OP1. The radius (radius of curvature) of the edge 30 of the aperture OP1 is, for example, 25 μm or more, and in one example the radius is 200 μm, but is not limited to that of this example. The area of the aperture OP2 is smaller than the area of the aperture OP1. In other words, the radius of the edge of the aperture OP2 is smaller than the radius of the edge 30 of the aperture OP1.

The partition 7 is disposed along the edge 30 of the aperture OP1. The partition 7 includes segments 7A, 7B, 7C, and 7D. The segments 7A, 7B, 7C, and 7D each have an L-letter shape. Gaps G1 are formed, respectively, between the segments 7A and 7B adjacent to each other along the X direction, between the segments 7C and 7D adjacent to each other along the X direction, between the segments 7A and 7D adjacent to each other along the Y direction, and between the segments 7B and 7C adjacent to each other along the Y direction.

In the configuration of this embodiment as well, advantageous effects similar to those of the first embodiment can be obtained. In this embodiment, the aperture OP1 is formed into circular, and thus the peeling off of the multilayer films FL1, FL2, and FL3 can be further suppressed; therefore such a portion that is likely to become a starting point for peeling off is not formed. As a result, the yield in the manufacturing process can be improved.

### Eighth Embodiment

FIG. 34 is a plan view schematically showing the region including the pads PD in the peripheral area SA or the margin portion MP in this embodiment. The example shown in FIG. 34 is different in the shape of the partition 7 compared to the configuration example shown in FIG. 33.

The partition 7 has approximately a circular shape in plan view. The partition 7 is disposed at a certain distance from the edge 30 of the aperture OP1. In other words, the partition 7 is disposed parallel to the edge 30 of the aperture OP1. In other words, the distance W2 from the edge 30 of the aperture OP1 to the partition 7 is constant along the edge 30 of the aperture OP1.

The partition 7 has segments 7A, 7B, 7C, and 7D. The segments 7A, 7B, 7C, and 7D each have a circular arc shape. The segments 7A, 7B, 7C, and 7D are arranged in the circumferential direction at intervals. Gaps G1 are each formed between each adjacent pair of the segments 7A, 7B, 7C, and 7D arranged in the circumferential direction.

In the configuration of this embodiment as well, advantageous effects similar to those of the first embodiment can be obtained. In this embodiment, the segments 7A, 7B, 7C, 7D are each formed into an arc shape, and therefore, the distance from the edge 30 can be to keep constant, and the distance between the partition 7 and the edge 30 can be reduced compared to the seventh embodiment.

In the example shown in FIGS. 33 and 34, the partition 7 includes segments 7A, 7B, 7C, and 7D, but the partition 7 may be formed to surround the aperture OP1. In other words, the partition 7 may be formed so as to be integrated as one body so that there is no gap G1.

### Ninth Embodiment

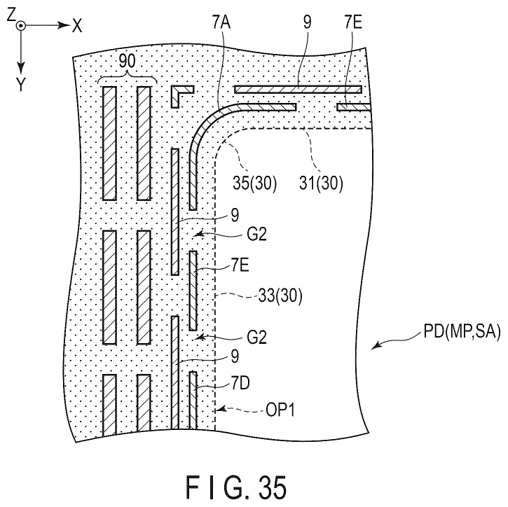

FIG. 35 is a plan view schematically showing the region including the pads PD in the peripheral area SA or the margin portion MP in this embodiment. In FIG. 35, the vicinity of the round portion 35 of the aperture OP1 is shown in an enlarged view. The edge 30 of the aperture OP1 includes edges 31 and 33 and a round portion 35. The partition 7 is disposed along the edge 30 of the aperture OP1.

The partition 7 includes segments 7A and 7D. When the segment 7A is focused, the segment 7A has an arc shape along round portion 35. The segment 7A is separated apart from the segment 7D in the Y direction.

When the vicinity of the edge 33 is focused, the partition 7 further includes a segment 7E. The segment 7E is located between the segment 7A and the segment 7D adjacent to each other. The segment 7E has a linear shape along the Y direction.

The segment 7E is disposed to be spaced apart from the segments 7A and 7D along the Y direction. Gaps G2 are formed, respectively, between the segment 7A and the segment 7E and between the segment 7D and the segment 7E.

The display device motherboard 100 (display device DSP) may further comprise a partition 9 (third partition). The partition 9 is disposed so as to overlap the gaps G2 on an outer side of the partition 7. More specifically, the partition 9 overlaps the gaps G2 as viewed in terms of the X direction. The distance of the partition 9 along the Y direction is greater than the distance of the gap G2 along the Y-direction, for example.

The partition 9 includes a conductive lower portion disposed on the inorganic insulating layer 5 and an upper portion disposed on the lower portion, though not shown in the figure. The upper portion has a width greater than that of the lower portion. The display device motherboard 100 (display device DSP) may further comprise a partition 90. The partition 90 is disposed on an outer side of the partition 9.

In the configuration of this embodiment as well, advantageous effects similar to those of the first embodiment can be obtained. In this embodiment, the partition 9 is arranged so as to overlap the gaps G2 on an outer side of the partition 7.

With this configuration, even if the peeling off of the multilayer films FL1, FL2, and FL3 occurs through a gap G2, the expansion of the peeling off can be suppressed by the partition 9. As a result, the yield in the manufacturing process can be improved.

The segment 7E described using FIG. 35 can be applied to each of the embodiments described with reference to FIGS. 29, 30, 32, and 33. Note that there may be a plurality of segments 7E arranged so as to be spaced apart from each other in the X direction and the Y direction.

### Tenth Embodiment

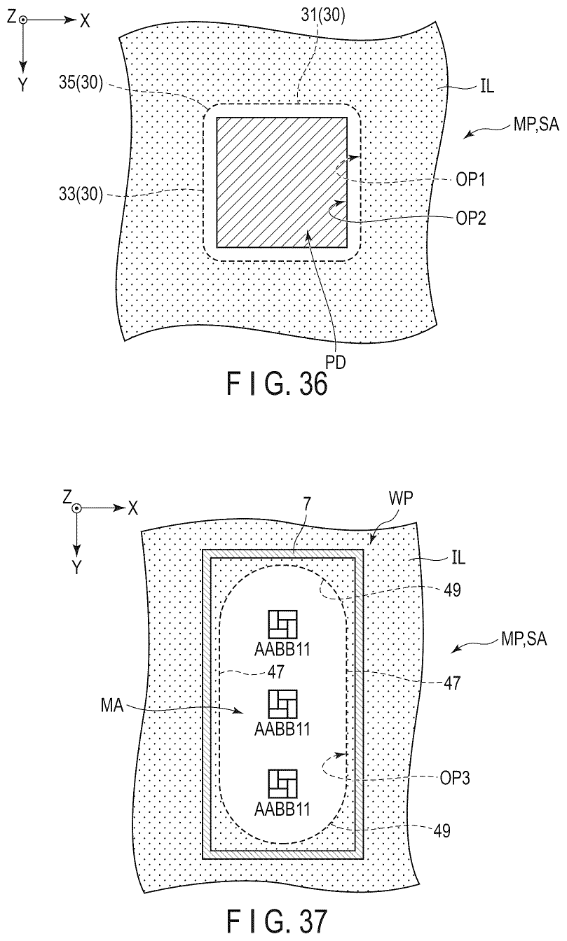

FIG. 36 is a plan view schematically showing the region including the pads PD in the peripheral area SA or the margin portion MP in this embodiment. In the example shown in FIG. 36, the partition 7 is not located on an outer side of the aperture OP1. In this case, the edge 30 of the aperture OP1 has a round portion 35. The radius of curvature R1 of the round portion 35 (shown in FIG. 9) is 25 μm or more, as described above.

With the configuration of this embodiment, it is also possible to improve the yield in the manufacturing process. More specifically, the edge 30 of the aperture OP1 has a rounded portion 35. Here, the corner portions are rounded, and therefore the corner portions are less likely to become a starting point for peeling off. Thus, the peeling off of the multilayer films FL1, FL2, and FL3 can be suppressed.

Subsequently, the shapes of the apertures OP1 and OP3 applicable to each of the above-provided embodiments will be described.

FIG. 37 is a diagram illustrating another shape of the aperture OP3 applicable to the window portions WP. The aperture OP3 has an elongated circular shape that is long along the Y direction. The edge 40 of the aperture OP3 includes a pair of edges 47 extending along the Y direction and a pair of round portions 49 connecting the end portions of the pair of edges 47. The radius of curvature of the round portions 49 is 25 μm or more.

The partition 7 is provided to surround the aperture OP3 on an outer side of the aperture OP3. Note that the partitions 7 may be disposed at a certain distance from the edge 40 of the aperture OP3. The partition 7 may include a plurality of segments spaced apart from each other.

Here, the descriptions are made in connection with the apertures OP3, but note that a similar shape may be applied to the aperture OP1 as well. The shapes applicable to the apertures OP1 and OP3 include not only circular (as shown in FIGS. 33 and 34) and elongated circular shapes, but also elliptical shapes.

Based on the display devices and motherboards for display device described above as embodiments of the invention, a person having ordinary skill in the art may achieve display devices and display device motherboards with arbitral design changes; however, as long as they fall within the scope and spirit of the present invention, all of such display devices and display device motherboards are encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A display device comprising:
a substrate;
an organic insulating layer disposed above the substrate over a display area in which a plurality of display elements are disposed and over a peripheral area around the display area;
a first partition disposed between the display elements adjacent to each other above the organic insulating layer; and
a second partition disposed in the peripheral area,
wherein
the first partition and the second partition each include a conductive lower portion and an upper portion protruding from a side surface of the lower portion,
the organic insulating layer includes an aperture in the peripheral area, and
the second partition is disposed along an edge of the aperture on an outer side of the aperture.

2. The display device of claim 1, wherein
the aperture comprises a first edge extending along a first direction, a second edge extending along a second direction which intersects the first direction, and a corner portion which connects the first edge and the second edge, and
at least a part of the second partition is disposed on an outer side of the corner portion.

3. The display device of claim 2, wherein
the second partition is formed 50 μm or more from the second edge along the first direction and 50 μm or more from the first edge along the second direction.

4. The display device of claim 3, wherein
the corner portion has an arc shape.

5. The display device of claim 4, wherein
the corner portion has a radius of curvature of 25 μm or more.

6. The display device of claim 1, wherein
the aperture has a circular shape.

7. The display device of claim 1, wherein
the second partition surrounds the aperture.

8. The display device of claim 1, wherein
the second partition is disposed at a fixed distance from the edge of the aperture on an outer side of the aperture.

9. The display device of claim 1, wherein
the second partition includes a plurality of segments spaced apart from each other.

10. The display device of claim 9, further comprising a third partition disposed so as to overlap a gap between each adjacent pair of the plurality of segments, on an outer side of the second partition.

11. A motherboard for a display device, comprising:
a panel portion including a display area which displays images and a peripheral area around the display area;
a margin portion on an outer side of the panel portion;
an organic insulating layer disposed over the panel portion and the margin portion;
a first partition disposed in the display area above the organic insulating layer; and
a second partition disposed in the margin portion,
wherein
the first partition and the second partition each include a conductive lower portion and an upper portion protruding from a side surface of the lower portion,
the organic insulating layer includes an aperture in the margin portion, and
the second partition is disposed along an edge of the aperture on an outer side of the aperture.

12. The motherboard for the display device, of claim 11, wherein
the aperture comprises a first edge extending along a first direction, a second edge extending along a second direction which intersects the first direction, and a corner portion which connects the first edge and the second edge, and
at least a part of the second partition is disposed on an outer side of the corner portion.

13. The motherboard for the display device, of claim 12, wherein
the second partition is formed 50 μm or more from the second edge along the first direction and 50 μm or more from the first edge along the second direction.

14. The motherboard for the display device of claim 13, wherein
the corner portion has an arc shape.

15. The motherboard for the display device, of claim 14, wherein
the corner portion has a radius of curvature of 25 μm or more.

16. The motherboard for the display device, of claim 11, wherein
the aperture has a circular shape.

17. The motherboard for the display device, of claim 11,
wherein the second partition surrounds the aperture.

18. The motherboard for the display device, of claim 11, wherein
the second partition is disposed at a fixed distance from the edge of the aperture on an outer side of the aperture.

19. The motherboard for the display device, of claim 11, wherein
the second partition includes a plurality of segments spaced apart from each other.

20. The motherboard for the display device, of claim 19, further comprising a third partition disposed so as to overlap a gap between each adjacent pair of the plurality of segments, on an outer side of the second partition.
